(19) United States
(12) Patent Application Publication
(10) Pub. No.: US 2018/0115288 A1
(43) Pub. Date: Apr. 26, 2018

(54) ARITHMETIC METHOD, BASE STATION DEVICE, AND ARITHMETIC CIRCUIT

(71) Applicant: FUJITSU LIMITED, Kawasaki-shi (JP)

(72) Inventors: Shunichi KONNO, Sendai (JP); Akira Toyomane, Sendai (JP); Yoshihiro GONAI, Iwanuma (JP); TAKESHI AKUTAGAWA, Kawasaki (JP)

(73) Assignee: FUJITSU LIMITED, Kawasaki-shi (JP)

(21) Appl. No.: 15/713,210

(22) Filed: Sep. 22, 2017

(30) Foreign Application Priority Data
Oct. 24, 2016 (JP) 2016-208023

(51) Int. Cl. H03F 1/32; H03F 3/21; H03F 1/30

(52) U.S. Cl. CPC H03F 1/3282; H03F 3/21; H03F 1/3247; H01Q 3/34; H03F 2201/3233; H03F 2201/3212; H03F 1/304

(57) ABSTRACT

An arithmetic method calculates a first correction coefficient for correction distortion due to a power amplifier based on a first feedback signal that has been fed back from an output of the power amplifier and an input signal before being input to the power amplifier. The arithmetic method also calculates a second correction coefficient for correcting the phase and amplitude of a signal to be output from a filter disposed behind the power amplifier, based on a second feedback signal that has been fed back from an output of the filter and the input signal.

### CROSS-REFERENCE TO RELATED APPLICATION

This application is based upon and claims the benefit of priority of the prior Japanese Patent Application No. 2016-208023, filed on Oct. 24, 2016, the entire contents of which are incorporated herein by reference.

### FIELD

The embodiments discussed herein are an arithmetic method, a base station device, and an arithmetic circuit.

### BACKGROUND

Base station devices that perform radio communications with radio terminals such as smartphones and mobile terminals use power amplifiers in their transmission side. The power amplifiers have linear input and output characteristics in a low output range, while having nonlinear input and output characteristics due to saturation in a high output range. For example, when the power amplifier is operated at high efficiency in the vicinity of a saturation region, the power amplifier has nonlinear input and output characteristics. In this case, nonlinear distortion occurs. When the nonlinear distortion is represented by a distortion function f(p), side lobes are generated in a frequency spectrum in the vicinity of the distortion function f(0) in the waveform of a transmission signal output from the power amplifier. As a result, the transmission signal leaks into adjacent channels, thus causing adjacent channel interference. In other words, the nonlinear distortion characteristics of the power amplifier cause increased power of the transmission signal that leaks into the adjacent channels. Therefore, an increasing number of the base station devices perform digital pre-distortion (DPD).

DPD is a process in which a distortion component having the inverse characteristics of the distortion characteristics of the power amplifier is superimposed on a transmission signal before being input to the power amplifier, in order to improve the distortion characteristics of the power amplifier. By superimposing the distortion component having the inverse characteristics on the transmission signal, distortion is reduced in a transmission signal that has passed through the power amplifier, and hence the distortion characteristics of the power amplifier are corrected. For example, a DPD function unit for performing DPD has an arithmetic unit and a correction unit. The arithmetic unit calculates an error between a transmission signal before being input to the power amplifier and a transmission signal that has been fed back from an output of the power amplifier through a feedback path. The arithmetic unit calculates a correction coefficient (correction value) to correct the distortion characteristics due to the power amplifier based on the calculated error, and stores the correction coefficient in a table. The correction unit applies the correction coefficient stored in the table to the transmission signal before being input to the power amplifier, to correct the distortion characteristics due to the power amplifier.

On the other hand, some base station devices perform antenna beam forming. The antenna beam forming is a technique of providing directivity in radio waves, to allow adjacent base stations to use the same frequency band. The antenna beam forming has the effect of significantly increasing usage efficiency of the radio waves. This technique allows an increase in transmission areas of the radio waves. The base station device can transmit radio waves while preventing interference with other radio waves emitted from other adjacent base stations and terminals. For example, the base station device can concentrate the radio waves on the direction of a radio terminal with which a communication is to be performed, while preventing the radio waves from reaching another radio terminal that is performing a communication with another radio station device. To transmit the radio waves in a concentrated manner, the phase and power of a signal to be transmitted from each of a plurality of antennas are changed. The antenna beam forming uses an array antenna principle. When a transmission side has an array antenna function, the base station device has a plurality of transmission units (branches) corresponding to the plurality of antennas. Therefore, when the antenna beam forming is performed, antenna calibration (ACAL) is performed.

ACAL is a process for adjusting the phase and amplitude of radio waves emitted from a plurality of antennas. For example, when antenna beam forming is performed, a phase difference is set between beam angles predetermined in the antennas. The phase difference is set based on the relationship between antenna elements. As a precondition for setting the phase difference, a phase error is calibrated between the branches. Since the phase varies depending on variations in environmental temperature, variations in power voltage, and the like, ACAL is performed at certain intervals to correct variations in the phase and amplitude of transmission signals. For example, an ACAL function unit for performing ACAL has an arithmetic unit and a correction unit. The arithmetic unit calculates an error between a transmission signal before being input to an analog circuit and a transmission signal that has been fed back from an output of a bandpass filter of the analog circuit through a feedback path. The arithmetic unit calculates a correction coefficient (correction value) for correcting variations in the phase and amplitude of the transmission signal occurring in the analog circuit based on the calculated error, and stores the correction coefficient in a table. The correction unit applies the correction coefficient stored in the table to the transmission signal before being input to the analog circuit, to correct the variations in the phase and amplitude of the transmission signal occurring in the analog circuit.

For example, when performing DPD and ACAL in the plurality of branches, the DPD function units, the ACAL function units, and the feedback paths the numbers of which correspond to the number of the branches are provided. Thus, there is a problem of increasing the circuit size of the analog circuit and the like. To solve this problem, there is a conventional technique in which the feedback path is shared between the DPD function unit and the ACAL function unit, and switched by a switch or the like in a time division manner.
Patent Document 1: Japanese Laid-Open Patent Publication No. 2006-094043
Patent Document 2: Japanese National Publication of International Patent Application No. 2006-503487
Patent Document 3: Japanese Laid-Open Patent Publication No. 2002-246825
Patent Document 4: Japanese National Publication of International Patent Application No. 2001-510668

However, in the conventional technique described above, since the feedback path is shared between the DPD function unit and the ACAL function unit, power consumed by the arithmetic process is increased. For example, an output of the bandpass filter corresponds to a common feedback point to the DPD function unit and the ACAL function unit. In this case, the ACAL function unit compares between a transmission signal before being input to the power amplifier and a signal that has been fed back from the output of the bandpass filter, thus allowing maintaining the performance of the ACAL. However, since the transmission signal has passed through the bandpass filter, the transmission signal that has been fed back from the output of the bandpass filter has distortion, in addition to the distortion characteristics due to the power amplifier. Thus, when the DPD function unit compares between the transmission signal before being input to the power amplifier and the transmission signal that has been fed back from the output of the bandpass filter, the number of loops is increased in the arithmetic process. This causes an increase in time for the arithmetic process, until the correction coefficient converges within an optimal correction coefficient range. As a result, the arithmetic process requires increased power consumption.

Also, in the conventional technique, when DPD and ACAL are performed in the branches, an arithmetic circuit (arithmetic unit) is provided in each of the DPD function unit and the ACAL function unit, thus causing an increase in circuit size.

### SUMMARY

According to an aspect of an embodiment, an arithmetic method includes calculating a first correction coefficient for correcting distortion due to a power amplifier, based on a first feedback signal that has been fed back from an output of the power amplifier and an input signal before being input to the power amplifier; and calculating a second correction coefficient for correcting a phase and an amplitude of a signal to be output from a filter disposed behind the power amplifier, based on a second feedback signal that has been fed back from an output of the filter and the input signal.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram of an example of a base station device according to a first embodiment;

FIG. 2 is a graph that depicts an example of a signal delay;

FIG. 3 is a block diagram that depicts an example of an arithmetic unit;

FIG. 4 is a graph that depicts an example of a correction image by DPD;

FIG. 5 is a graph that depicts an example of a correction image by ACAL after DPD;

FIG. 6 is an enlarged view of an X portion of FIG. 5;

FIG. 7 is a timing chart that depicts an example of simplification of ACAL;

FIG. 8 is a flowchart that depicts an example of the operation of the base station device according to the first embodiment;

FIG. 9 is a flowchart that depicts an example of DPD in FIG. 8;

FIG. 10 is a flowchart that depicts an example of a BPF correction process in FIG. 8;

FIG. 11 is a block diagram that depicts an example of a base station device according to a second embodiment;

FIG. 12 is a drawing that explains the intermittent operation of ACAL;

FIG. 13 is a flowchart that depicts an example of the operation of the base station device according to the second embodiment; and

FIG. 14 is a drawing that depicts an example of the hardware configuration of a base station device.

### DESCRIPTION OF EMBODIMENTS

Preferred embodiments of the present invention will be explained with reference to accompanying drawings. It is noted that the following embodiments do not limit the scope of the technique disclosed.

### [a] First Embodiment

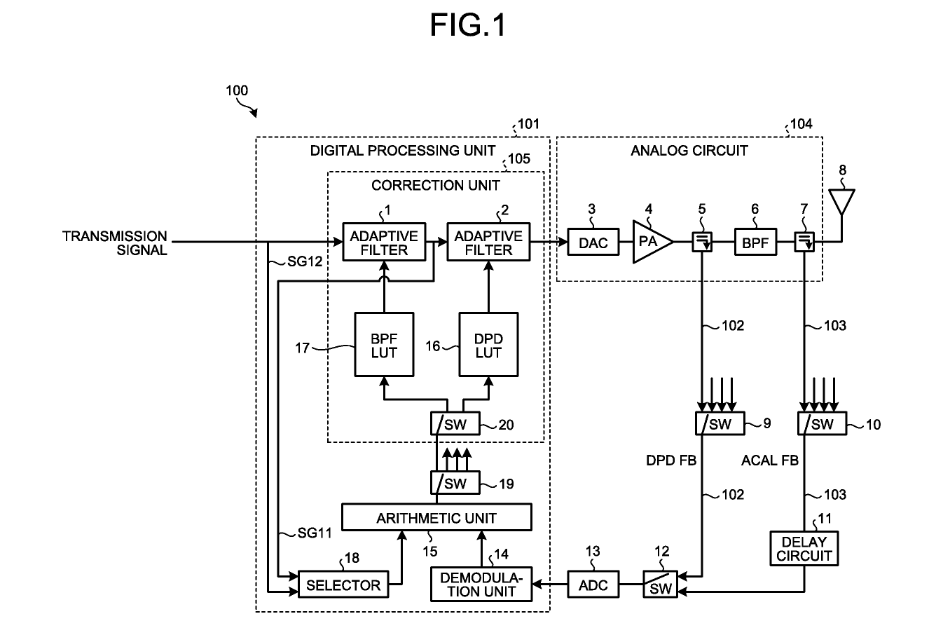

FIG. 1 is a block diagram that depicts an example of a base station device 100 according to a first embodiment. The base station device 100 includes a digital processing unit 101, an analog circuit 104, an antenna 8, switches (SWs) 9, 10, and 12, a delay circuit 11, and an analog-to-digital converter (ADC) 13.

The analog circuit 104 includes a digital-to-analog converter (DAC) 3, a power amplifier (PA) 4, circulators 5 and 7, and a bandpass filter (BPF) 6.

The digital processing unit 101 includes a correction unit 105, a demodulation unit 14, an arithmetic unit 15, a selector 18, and a switch (SW) 19. The correction unit 105 includes adaptive filters 1 and 2, a DPD lookup table (DPD LUT) 16, a BPF lookup table (BPF LUT) 17, and a switch (SW) 20.

The base station device 100 further has a plurality of transmission units (branches). Each of the branches is provided with a correction unit 105, an analog circuit 104, and an antenna 8.

The adaptive filter 1 receives a transmission signal, i.e., a digital signal. The adaptive filter 1 applies a BPF correction coefficient stored in the BPF LUT 17 to the transmission signal. In other words, the adaptive filter 1 calculates the product of the BPF correction coefficient stored in the BPF LUT 17 and the transmission signal. This corrects variations in the phase and amplitude of the transmission signal that occur in the BPF 6. The adaptive filter 1 outputs the corrected transmission signal to the adaptive filter 2.

The adaptive filter 2 receives the transmission signal from the adaptive filter 1. The adaptive filter 2 applies a DPD correction coefficient stored in the DPD LUT 16 to the transmission signal. In other words, the adaptive filter 2 calculates the product of the DPD correction coefficient stored in the DPD LUT 16 and the transmission signal. This corrects nonlinear distortion characteristics of the PA 4 and variations in the phase and amplitude of the transmission signal that occur until an output end of the PA 4. The adaptive filter 2 outputs the corrected transmission signal to the DAC 3.

DAC 3 receives the transmission signal from the adaptive filter 2. The DAC 3 converts the transmission signal into an analog signal, and outputs the analog signal to the PA 4.

The PA 4 receives the transmission signal from the DAC 3. The PA 4 amplifies the power of the transmission signal, and outputs the transmission signal to the circulator 5.

The circulator 5 receives the transmission signal from the PA 4. The circulator 5 outputs the transmission signal to the BPF 6. The circulator 5 also outputs the transmission signal to the SW 12 through the SW 9 and a DPD feedback path (DPD FB) 102.

The SW 9 is provided in the DPD FB 102. To be more specific, the SW 9 has a plurality of switching elements each of which corresponds to each of the branches, and each switching element is provided in the DPD FB 102. For example, sequentially turning on the switching elements of the SW 9 sequentially activates the DPD FBs 102 of the branches. In other words, in each branch, the circulator 5 and the SW 12 are connected through the DPD FB 102.

The BPF 6 receives the transmission signal from the circulator 5. The BPF 6 passes a specific frequency band of the transmission signal, and attenuates the other frequency band of the transmission signal. The signal having passed through the BPF 6 is output to the circulator 7 as a transmission signal.

The circulator 7 receives the transmission signal from the BPF 6. The circulator 7 outputs the transmission signal to the antenna 8. The antenna 8 transmits the transmission signal received from the circulator 7. The circulator 7 outputs the transmission signal to the SW 12 through the SW 10, an ACAL feedback path (ACAL FB) 103, and the delay circuit 11.

The SW 10 is provided in the ACAL FB 103. To be more specific, the SW 10 has a plurality of switching elements each of which corresponds to each of the branches, and each switching element is provided in the ACAL FB 103. For example, sequentially turning on the switching elements of the SW 10 sequentially activates the ACAL FBs 103 of the branches. In other words, in each branch, the circulator 7 and the SW 12 are connected through the ACAL FB 103.

The SW 12 switches between the feedback paths in accordance with a control signal in a time division manner. The control signal has a first value or a second value. For example, when the control signal has the first value, the SW 12 selects the DPD FB 102. In this case, the SW 12 outputs the transmission signal that has been fed back from the output of the PA 4 through the circulator 5, the SW 9, and the DPD FB 102, to the ADC 13. When the control signal has the second value, the SW 12 selects the ACAL FB 103. In this case, the SW 12 outputs the transmission signal that has been fed back from the output of the BPF 6 through the circulator 7, the SW 10, and the ACAL FB 103, to the ADC 13. The switching timing of the control signal is determined based on a process delay.

The delay circuit 11 is disposed in the ACAL FB 103. To be more specific, the delay circuit 11 is disposed in the ACAL FB 103 between the SW 10 and the SW 12. When switching between the DPD FB 102 and the ACAL FB 103 in a time division manner, the delay circuit 11 applies a predetermined time delay to the transmission signal that has been fed back from the output of the BPF 6 through the circulator 7, the SW 10, and the ACAL FB 103.

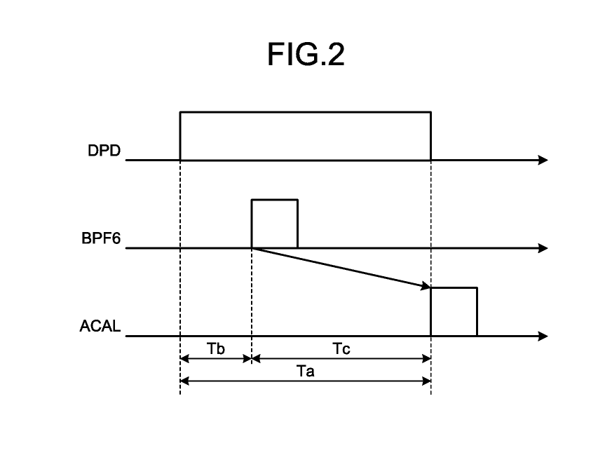

FIG. 2 is a graph that depicts an example of a signal delay. For example, a predetermined time Tc is determined based on a process time Ta and a process time Tb. More specifically, the process time Ta represents process time for the arithmetic unit 15 to perform DPD, and the process time Tb represents process time for the transmission signal to pass through the BPF 6. The predetermined time Tc represents time in which the process time Tb is subtracted from the process time Ta. Therefore, the transmission signal having a delay of the predetermined time Tc is synchronized with the transmission signal that has been fed back from the output of the PA 4 through the circulator 5, the SW 9, and the DPD FB 102.

As depicted in FIG. 1, the ADC 13 receives the transmission signal from the SW 12. The ADC 13 converts the transmission signal into a digital signal, and outputs the digital signal to the demodulation unit 14.

The demodulation unit 14 receives the transmission signal from the ADC 13. The demodulation unit 14 demodulates the transmission signal, and outputs the demodulated transmission signal to the arithmetic unit 15.

The selector 18 selects a transmission signal in accordance with the control signal. For example, when the control signal has the first value, the selector 18 selects a transmission signal SG11. When the control signal has the second value, the selector 18 selects a transmission signal SG12. The transmission signal SG11 is a transmission signal that is output from the adaptive filter 1 before being input to the adaptive filter 2. The transmission signal SG12 is a transmission signal before being input to the adaptive filter 1. Thus, when the control signal has the first value, the selector 18 outputs the transmission signal SG11 to the arithmetic unit 15. When the control signal has the second value, the selector 18 outputs the transmission signal SG12 to the arithmetic unit 15.

The SW 19 is provided between the arithmetic unit 15 and the correction unit 105. To be more specific, the SW 19 has a plurality of switching elements each of which corresponds to each branch. For example, sequentially turning on the switching elements of the SW 19 sequentially activates the branches. In other words, in each branch, the arithmetic unit 15 is connected to the correction unit 105.

The SW 20 of the correction unit 105 selects a lookup table in accordance with the control signal. For example, when the control signal has the first value, the SW 20 selects the DPD LUT 16. In this case, the arithmetic unit 15 and the DPD LUT 16 are connected through the SWs 19 and 20. When the control signal has the second value, the SW 20 selects the BPF LUT 17. In this case, the arithmetic unit 15 and the BPF LUT 17 are connected through the SWs 19 and 20.

The arithmetic unit 15 performs arithmetic process in accordance with the control signal. For example, when the control signal has the first value, the arithmetic unit 15 performs DPD as the arithmetic process. In this case, the arithmetic unit 15 calculates an error between the transmission signal SG11 from the selector 18 and a first transmission signal from the demodulation unit 14. The first transmission signal from the demodulation unit 14 is a transmission signal that has been fed back from the PA 4 through the circulator 5, the SW 9, the DPD FB 102, the SW 12, the ADC 13, and the demodulation unit 14. The arithmetic unit 15 calculates the DPD correction coefficient to correct the nonlinear distortion characteristics of the PA 4 and the variations (hereinafter referred to as first variations) in the phase and amplitude of the transmission signal that occur until the output end of the PA 4, based on the calculated error. When the control signal has the first value, the SW 20 selects the DPD LUT 16. Thus, the arithmetic unit 15 stores the calculated DPD correction coefficient in the DPD LUT 16 through the SW 19 and the SW 20. The adaptive filter 2 calculates the product of the DPD correction coefficient stored in the DPD LUT 16 and the transmission signal, so that the distortion characteristics by the PA 4 and the first variations are corrected.

When the control signal has the second value, the arithmetic unit 15 performs ACAL as the arithmetic process. In this case, the arithmetic unit 15 calculates an error between the transmission signal SG12 from the selector 18 and a second transmission signal from the demodulation unit 14. The second transmission signal from the demodulation unit 14 is a transmission signal that has been fed back from the BPF 6 through the circulator 7, the SW 10, the ACAL FB 103, the delay circuit 11, the SW 12, the ADC 13, and the demodulation unit 14. The arithmetic unit 15 calculates the BPF correction coefficient to correct the variations (hereinafter referred to as second variations) in the phase and amplitude of the transmission signal that occur in the BPF 6, based on the calculated error. When the control signal has the second value, the SW 20 selects the BPF LUT 17. Thus, the arithmetic unit 15 stores the calculated BPF correction coefficient in the BPF LUT 17 through the SWs 19 and 20. The adaptive filter 1 calculates the product of the BPF correction coefficient stored in the BPF LUT 17 and the transmission signal, so that the second variations are corrected.

Configuration of Arithmetic Unit

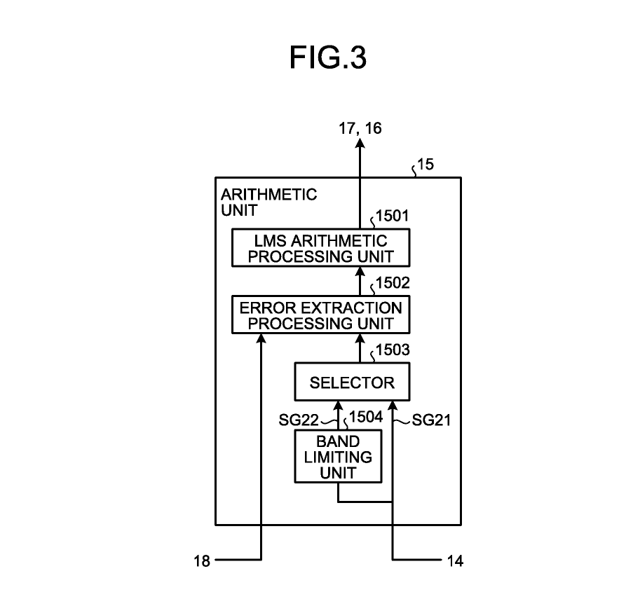

FIG. 3 is a block diagram that depicts an example of the arithmetic unit 15. The arithmetic unit 15 includes an LMS arithmetic processing unit 1501, an error extraction processing unit 1502, a selector 1503, and a band limiting unit 1504. The arithmetic unit 15 is an example of an arithmetic circuit.

The band limiting unit 1504 receives a transmission signal from the demodulation unit 14. The band limiting unit 1504 passes the same frequency band of the transmission signal as the BPF 6, and attenuates the other frequency band of the transmission signal. The signal having passed through the band limiting unit 1504 is output to the selector 1503.

The selector 1503 selects a transmission signal in accordance with the control signal. For example, when the control signal has the first value, the selector 1503 outputs a transmission signal SG21 to the error extraction processing unit 1502. The transmission signal SG21 is a first transmission signal from the demodulation unit 14. When the control signal has the second value, the selector 1503 outputs a transmission signal SG22 to the error extraction processing unit 1502. The transmission signal SG22 is a second transmission signal from the demodulation unit 14. Thus, when the control signal has the first value, the first transmission signal from the demodulation unit 14 is selected as the transmission signal SG21. When the control signal has the second value, the second transmission signal from the demodulation unit 14 that has been passed through the band limiting unit 1504 is selected as the transmission signal SG22.

The error extraction processing unit 1502 receives the transmission signals from the selector 18 and the selector 1503. For example, when the control signal has the first value, the selector 18 outputs the transmission signal SG11 to the error extraction processing unit 1502, and the selector 1503 outputs the transmission signal SG21 to the error extraction processing unit 1502. In this case, the error extraction processing unit 1502 receives the transmission signal SG11 from the selector 18, and receives the transmission signal SG21 from the selector 1503. The error extraction processing unit 1502 extracts an error between the transmission signal SG11 and the transmission signal SG21 as a first error, and outputs the first error to the LMS arithmetic processing unit 1501.

When the control signal has the second value, the selector 18 outputs the transmission signal SG12 to the error extraction processing unit 1502, and the selector 1503 outputs the transmission signal SG22 to the error extraction processing unit 1502. In this case, the error extraction processing unit 1502 receives the transmission signal SG12 from the selector 18, and receives the transmission signal SG22 from the selector 1503. The error extraction processing unit 1502 extracts an error between the transmission signal SG12 and the transmission signal SG22 as a second error, and outputs the second error to the LMS arithmetic processing unit 1501.

The LMS arithmetic processing unit 1501 updates a lookup table in accordance with the control signal. For example, when the control signal has the first value, the LMS arithmetic processing unit 1501 updates the DPD LUT 16. In this case, the LMS arithmetic processing unit 1501 receives the first error from the error extraction processing unit 1502. The LMS arithmetic processing unit 1501 calculates the DPD correction coefficient so as to make the first error equal to 0, by arithmetic process using, for example, a least mean square (LMS) algorithm. When the control signal has the first value, the SW 20 selects the DPD LUT 16. Therefore, the LMS arithmetic processing unit 1501 stores the DPD correction coefficient in the DPD LUT 16 through the SWs 19 and 20.

When the control signal has the second value, the LMS arithmetic processing unit 1501 updates the BPF LUT 17. In this case, the LMS arithmetic processing unit 1501 receives the second error from the error extraction processing unit 1502. The LMS arithmetic processing unit 1501 calculates the BPF correction coefficient so as to make the second error equal to 0, by arithmetic process using, for example, the LMS algorithm. When the control signal has the second value, the SW 20 selects the BPF LUT 17. Therefore, the LMS arithmetic processing unit 1501 stores the BPF correction coefficient in the BPF LUT 17 through the SWs 19 and 20.

Correction Image

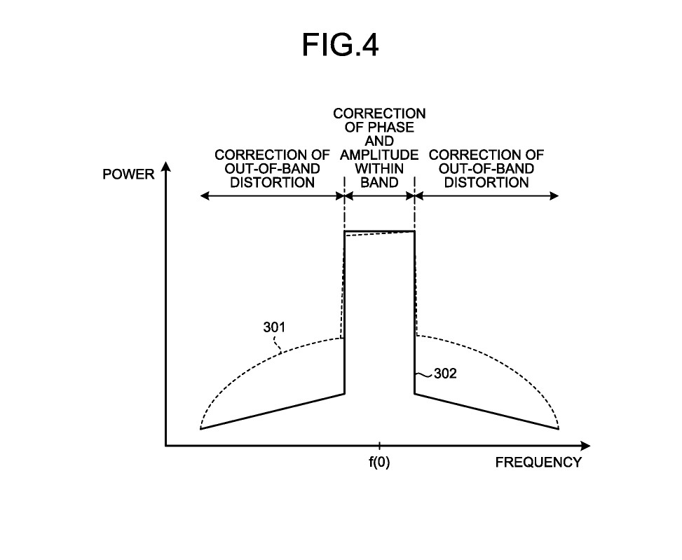

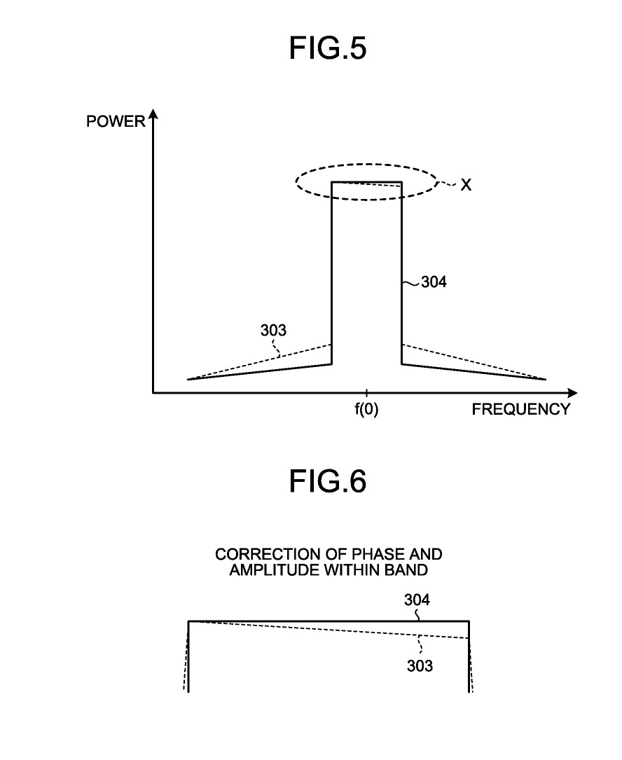

FIG. 4 is a graph that depicts an example of a correction image by DPD. FIG. 5 is a graph that depicts an example of a correction image by ACAL after DPD. FIG. 6 is an enlarged view of an X portion of FIG. 5.

For example, when the PA 4 is operated with high efficiency in the vicinity of a saturation region, the PA 4 has nonlinear input and output characteristics. In this case, nonlinear distortion occurs. When the nonlinear distortion is represented by a distortion function f(p), side lobes are generated in a frequency spectrum in the vicinity of the distortion function f(0) in the waveform of a transmission signal output from the PA 4, as depicted by a broken line 301 in FIG. 4. As a result, the transmission signal leaks into adjacent channels, thus causing adjacent channel interference. As depicted by a solid line 302 in FIG. 4, performing DPD corrects out-of-band distortion of a characteristic depicted by the broken line 301 in FIG. 4. In other words, the distortion characteristics by the PA 4 are corrected.

For example, when antenna beam forming is performed, a phase difference is set between beam angles predetermined in the antennas. The phase difference is set based on the relationship between antenna elements. As a precondition for setting the phase difference, a phase error is calibrated between the branches. The phase varies depending on variations in environmental temperature, variations in power voltage, and the like. Therefore, performing DPD also corrects the transmission signal to be output from the PA 4 for variations in phase and amplitude within the band, like the characteristics depicted by the solid line 302 in FIG. 4. In other words, the first variations are corrected.

The first variations mainly occur in accordance with variations in heat and power voltage and the like. On the other hand, since the BPF 6 is mainly constituted of passive components, variations in the phase and amplitude of the transmission signal to be output from the BPF 6 occur in accordance with variations in environmental temperature and the like. DPD corrects the first variations, as well as the distortion characteristics by the PA 4. Thus, the correction for the first variations can also be used in ACAL. In other words, the correction for the first variations is shared between DPD and ACAL. The commonalization facilitates simplifying ACAL. To be more specific, as depicted by a solid line 304 in FIGS. 5 and 6, performing ACAL, after DPD, corrects a characteristic depicted by a broken line 303 in FIGS. 5 and 6 (corresponding to a characteristic depicted by the solid line 302 in FIG. 4) for variations in phase and amplitude within the band. In other words, the second variations are corrected. Therefore, ACAL may correct the second variations.

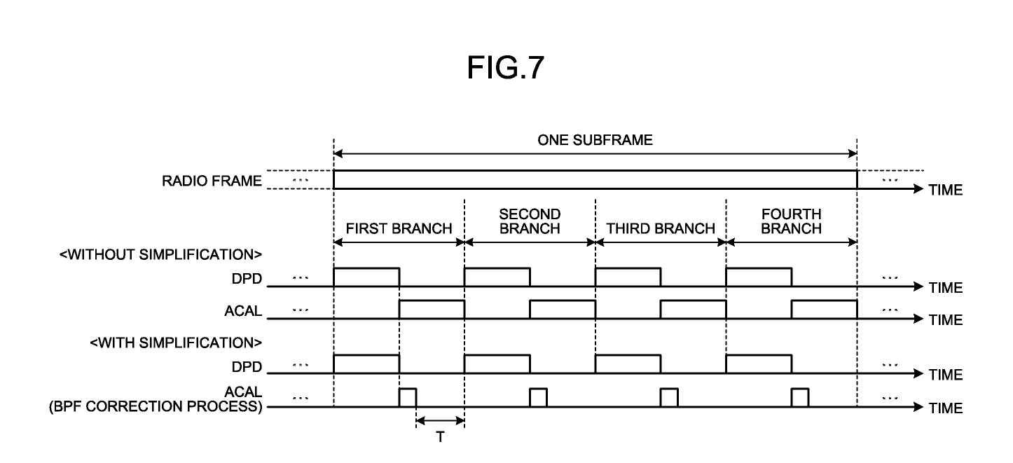

FIG. 7 is a timing chart that depicts an example of simplification of ACAL. FIG. 7 takes a case in which the number of the branches is four, and DPD and ACAL for the four branches are performed in one subframe as a radio frame, as an example.

First, when ACAL is not simplified, a DPD correction coefficient to correct the distortion characteristics by the PA 4 and the first variations is calculated in DPD. Owing to the DPD correction coefficient, the distortion characteristics by the PA 4 and the first variations are corrected. Next, an ACAL correction coefficient to correct variations (hereinafter referred to as third variations) in the phase and amplitude of the transmission signal occurring until the output end of the BPF 6 is calculated in ACAL. The third variations are corrected by the ACAL correction coefficient. However, the third variations include the first variations corrected by DPD and the second variations. Thus, when ACAL is not simplified, arithmetic process is performed to correct the first variations that have already been corrected by DPD and the second variations. This causes an increase in time for the arithmetic process, until the ACAL correction coefficient converges within an optimal correction coefficient range. In other words, this causes an increase in the number of loops in the arithmetic process. As a result, the arithmetic process requires increased power consumption.

Next, when ACAL is simplified, a DPD correction coefficient to correct the distortion characteristics by the PA 4 and the first variations is calculated in DPD. Owing to the DPD correction coefficient, the distortion characteristics by the PA 4 and the first variations are corrected. Next, in ACAL (BPF correction process), a BPF correction coefficient to correct the second variations after performing DPD is calculated. Owing to the BPF correction coefficient, the second variations are corrected. In other words, when ACAL is simplified, arithmetic process is performed to correct the second variations. Thus, when ACAL is simplified, as illustrated in FIG. 7, time needed for the arithmetic process to converge the BPF correction coefficient within an optimal correction coefficient range can be reduced by T, as compared with the case of not simplifying ACAL. As a result, it is possible to prevent an increase in power consumption for the arithmetic process.

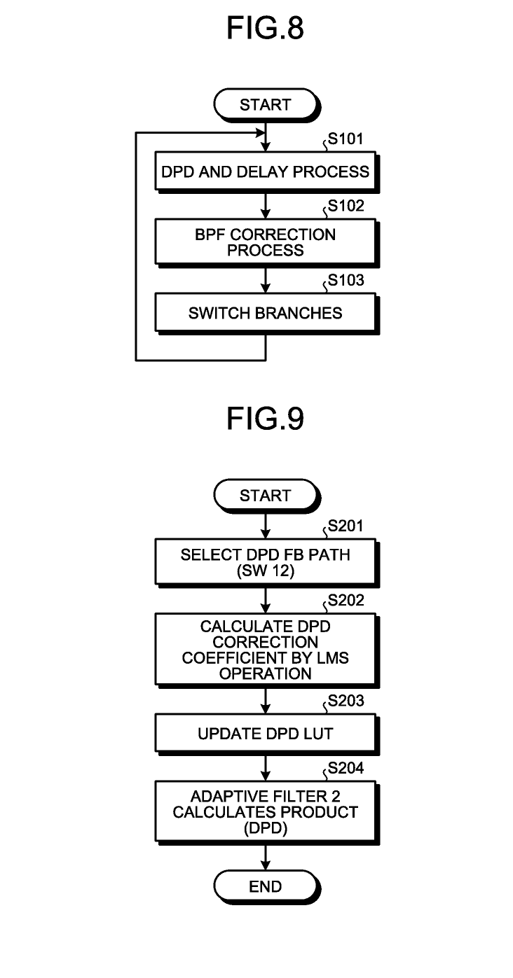

Example of Operation of Base Station Device Next, the operation of the base station device 100 according to the first embodiment will be described. FIG. 8 is a flowchart that depicts an example of the operation of the base station device according to the first embodiment.

First, DPD is performed (step S101). In step S101, the delay circuit 11 performs delay process. More specifically, the delay circuit 11 delays a transmission signal that has been fed back from the output of the BPF 6 through the circulator 7, the SW 10, and the ACAL FB 103 by a predetermined time Tc.

Next, after performing DPD, BPF correction process is performed as ACAL (step S102). Next, the branches are switched by the SWs 9, 10, and 19 (step S103), and the operation of the base station device 100 returns to step S101.

FIG. 9 is a flowchart that depicts an example of DPD in FIG. 8. First, a path of the DPD FB 102 is selected by the SW 12 (step S201). In this case, the selector 18 outputs a transmission signal SG11 to the error extraction processing unit 1502, while the selector 1503 outputs a transmission signal SG21 to the error extraction processing unit 1502. The SW 20 selects the DPD LUT 16.

The error extraction processing unit 1502 receives the transmission signal SG11 from the selector 18, and receives the transmission signal SG21 from the selector 1503. The error extraction processing unit 1502 extracts an error between the transmission signal SG11 and the transmission signal SG21 as a first error. The LMS arithmetic processing unit 1501 applies arithmetic process (hereinafter referred to as LMS operation) using the LMS algorithm to the first error. The LMS operation calculates a DPD correction coefficient to correct nonlinear distortion characteristics by the PA 4 and first variations (step S202). The LMS arithmetic processing unit 1501 stores the DPD correction coefficient in the DPD LUT 16 through the SWs 19 and 20, to update the DPD LUT 16 (step S203). The adaptive filter 2 calculates the product of the DPD correction coefficient stored in the DPD LUT 16 and the transmission signal, so that the distortion characteristics by the PA 4 and the first variations are corrected (step S204).

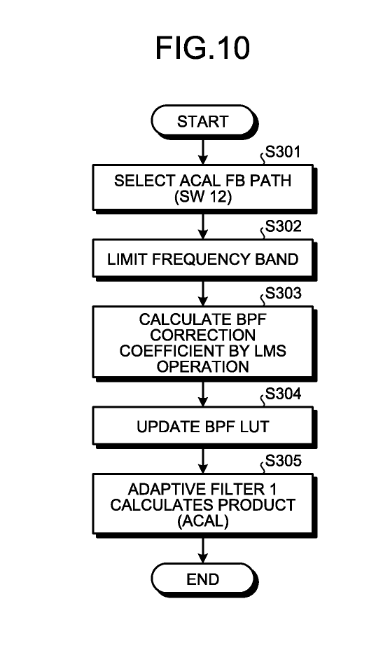

FIG. 10 is a flowchart that depicts an example of the BPF correction process in FIG. 8. First, a path of the ACAL FB 103 is selected by the SW 12 (step S301). In this case, the band limiting unit 1504 of the arithmetic unit 15 passes the same frequency band of the transmission signal having a delay of the predetermined time Tc as the BPF 6, and attenuates the other frequency band of the signal (step S302). The selector 18 outputs a transmission signal SG12 to the error extraction processing unit 1502, while the selector 1503 outputs a transmission signal SG22 that has passed through the band limiting unit 1504 to the error extraction processing unit 1502. The SW 20 selects the BPF LUT 17.

The error extraction processing unit 1502 receives the transmission signal SG12 from the selector 18, and receives the transmission signal SG22 from the selector 1503. The error extraction processing unit 1502 extracts an error between the transmission signal SG12 and the transmission signal SG22 as a second error. The LMS arithmetic processing unit 1501 applies the LMS operation to the second error. The LMS operation calculates a BPF correction coefficient to correct second variations (step S303). The LMS arithmetic processing unit 1501 stores the BPF correction coefficient in the BPF LUT 17 through the SWs 19 and 20, to update the BPF LUT 17 (step S304). The adaptive filter 1 calculates the product of the BPF correction coefficient stored in the BPF LUT 17 and the transmission signal, so that the second variations are corrected (step S305).

Effects of Embodiment

As described above, the base station device 100 according to this embodiment includes the PA 4, the filter (BPF 6) disposed behind the PA 4, and the arithmetic unit 15, i.e., the arithmetic circuit. The arithmetic unit 15 performs DPD and ACAL. In DPD, the arithmetic unit 15 calculates the first correction coefficient (DPD correction coefficient) to correct the distortion by the PA 4 based on the first feedback signal that has been fed back from the output of the PA 4 and the input signal before being input to the PA 4. In ACAL, the arithmetic unit 15 calculates the second correction coefficient (BPF correction coefficient) to correct the phase and amplitude of the signal to be output from the BPF 6, based on the second feedback signal that has been fed back from the output of the BPF 6 and the input signal. The correction by the DPD correction coefficient is shared between DPD and ACAL, and hence ACAL is simplified. In other words, ACAL performs only correction by the BPF correction coefficient. Thus, when ACAL is simplified, it is possible to reduce time needed for the arithmetic process to converge the BPF correction coefficient within the optimal correction coefficient range, as compared with the case of not simplifying ACAL. As a result, this embodiment prevents an increase in power consumed by the arithmetic process. The base station device 100 according to this embodiment performs DPD and ACAL in one arithmetic circuit (arithmetic unit 15). Therefore, this embodiment prevents an increase in circuit size.

The base station device 100 according to this embodiment further includes switches (SWs 9, 10, and 12). The SWs 9, 10, and 12 switch between the first feedback path (DPD FB 102) to feed back the output of the PA 4 and the second feedback path (ACAL FB 103) to feed back the output of the BPF 6 in a time division manner. This makes it possible to correct the first variations by the DPD correction coefficient, and thereafter correct the second variations by the BPF correction coefficient.

The base station device 100 according to this embodiment further includes the delay circuit 11. The delay circuit 11 delays the second feedback signal that has been fed back from the output of the BPF 6 through the ACAL FB 103 by the predetermined time Tc based on the process time Ta and the process time Tb, when switching between the DPD FB 102 and the ACAL FB 103 in a time division manner. The process time Ta represents process time for the arithmetic unit 15 to perform DPD. The process time Tb represents process time for the signal output from the PA 4 to pass through the BPF 6. The predetermined time Tc represents time in which the process time Tb is subtracted from the process time Ta. Therefore, the second feedback signal having a delay of the predetermined time Tc is synchronized with the first feedback signal that has been fed back from the output of the PA 4 through the DPD FB 102.

### [b] Second Embodiment

Configuration of Base Station Device

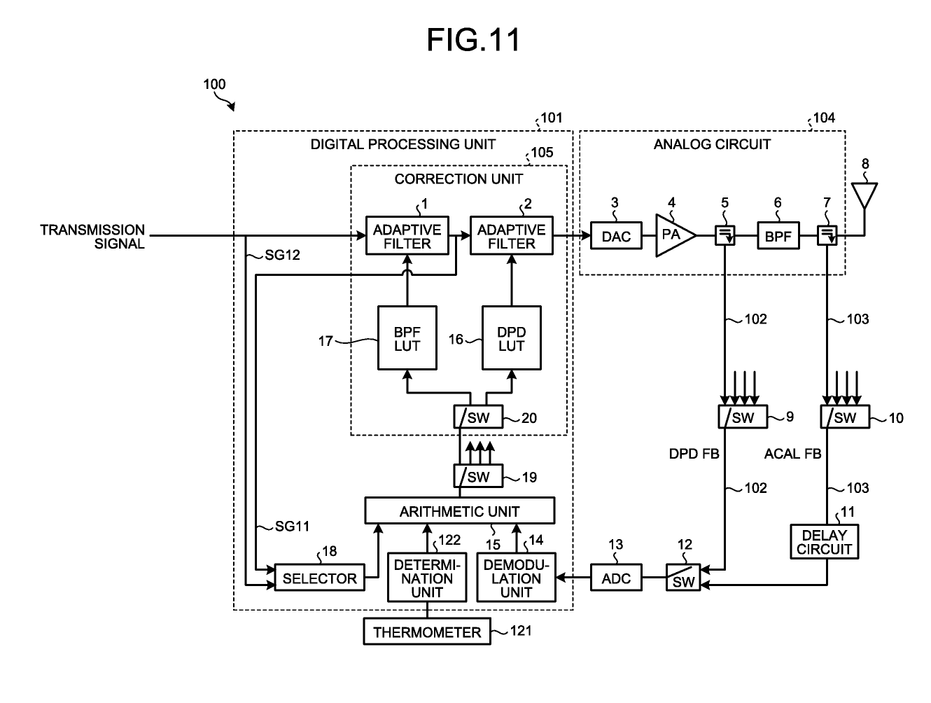

FIG. 11 is a block diagram that depicts an example of a base station device according to a second embodiment. In the second embodiment, the description of the same configuration and operation as those of the first embodiment are omitted.

A base station device 100 according to the second embodiment further includes a thermometer 121 to measure an environmental temperature. A digital processing unit 101 of the base station device 100 further includes a determination unit 122.

When BPF correction process is performed as ACAL, the determination unit 122 determines whether or not a BPF correction coefficient converges within an optimal correction coefficient range. When the BPF correction coefficient converges within the optimal correction coefficient range, the determination unit 122 calculates a temperature variation value. The temperature variation value is the difference between an environmental temperature measured by the thermometer 121 when the BPF correction coefficient converges within the optimal correction coefficient range and an environmental temperature that is measured at the present time by the thermometer 121. The determination unit 122 determines whether or not the absolute value of the temperature variation value is equal to or less than a set value, and outputs the determination result to the arithmetic unit 15.

The arithmetic unit 15 receives the determination result from the determination unit 122. When the determination result from the determination unit 122 indicates that the temperature variation value is equal to or less than the set value, the arithmetic unit 15 stops ACAL. While ACAL has been stopped, when the determination result from the determination unit 122 indicates that the temperature variation value exceeds the set value, the arithmetic unit 15 restarts ACAL.

As described in the first embodiment, since the BPF 6 is mainly constituted of the passive components, variations in the phase and amplitude of a transmission signal to be output from the BPF 6 occur in accordance with variations in environmental temperature and the like. Therefore, when the BPF correction coefficient converges within the optimal correction coefficient range by ACAL, ACAL is stopped if the variation value of the environmental temperature is equal to or less than the set value. This allows performing ACAL in an intermittent manner.

Intermittent Processing of ACAL

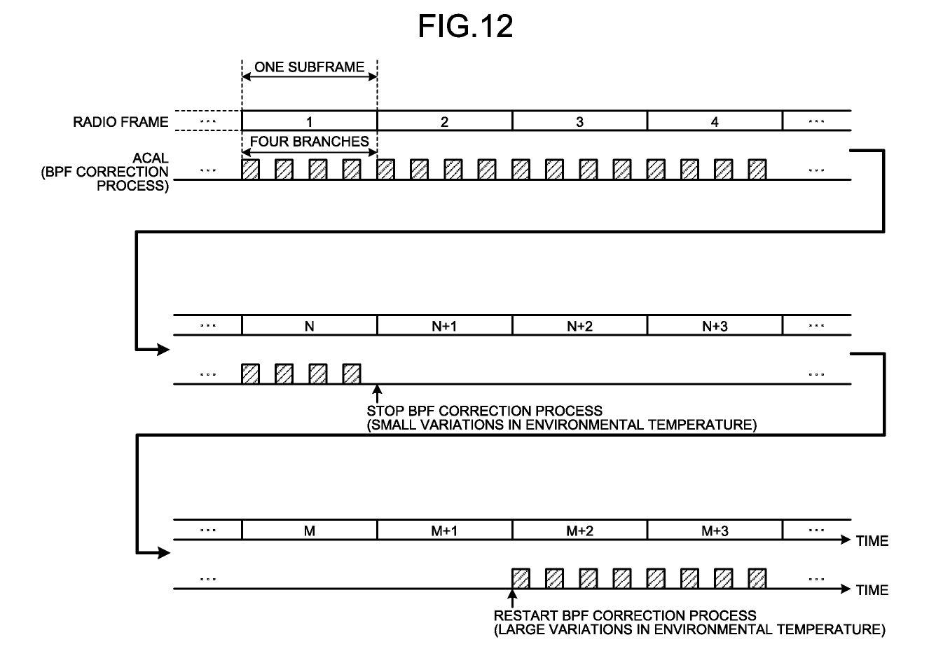

FIG. 12 is a drawing that explains the intermittent operation of ACAL. FIG. 12 takes a case in which the number of the branches is four, and ACAL for the four branches is performed in one subframe as a radio frame, as an example.

First, ACAL (BPF correction process) is performed in the first to Nth subframes (N is an integer larger than 4). As a result of this, the BPF correction coefficient converges within the optimal correction coefficient range. Next, since the temperature variation value is equal to or less than the set value in the (N+1)th to (M+1)th subframes (M is an integer larger than N+3), ACAL (BPF correction process) is stopped. Next, since the temperature variation value exceeds the set value in the (M+2) and later subframes, ACAL (BPF correction process) is performed. Intermittently performing ACAL allows a reduction in power consumption for ACAL in a period from the (N+1)th subframe to the (M+1)th subframe, as compared with the case of not performing ACAL in an intermittent manner.

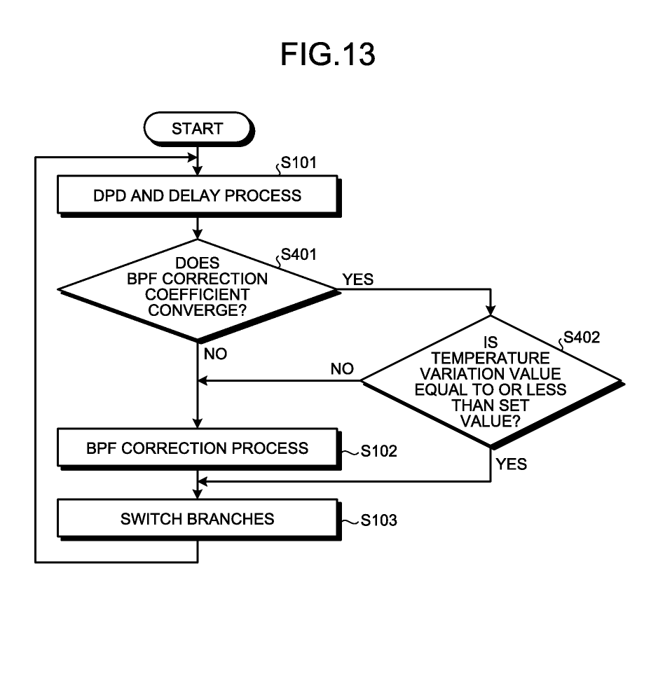

Example of Operation of Base Station Device Next, the operation of the base station device according to the second embodiment will be described. FIG. 13 is a flowchart that depicts an example of the operation of the base station device according to the second embodiment.

First, DPD is performed, and the delay circuit 11 performs delay process (step S101). Next, when a BPF correction coefficient does not converge within the optimal correction coefficient range (NO in step S401), BPF correction process is performed as ACAL (step S102). Next, the branches are switched by the SWs 9, 10, and 19 (step S103), and the operation of the base station device 100 returns to step S101.

On the other hand, when the BPF correction coefficient converges within the optimal correction coefficient range (YES in step S401), the determination unit 122 calculates a temperature variation value that is the difference between an environmental temperature when the BPF correction coefficient converges within the optimal correction coefficient range and an environmental temperature measured at the present time. The determination unit 122 determines whether or not the absolute value of the temperature variation value is equal to or less than a set value (step S402).

When the absolute value of the temperature variation value is equal to or less than the set value (YES in step S402), BPF correction process is not performed. Next, the branches are switched by the SWs 9, 10, and 19 (step S103), and the operation of the base station device 100 returns to step S101.

On the other hand, when the absolute value of the temperature variation value exceeds the set value (NO in step S402), BPF correction process is performed (step S102). Next, the branches are switched by the SWs 9, 10, and 19 (step S103), and the operation of the base station device 100 returns to step S101.

As described above, the base station device 100 according to this embodiment further includes the thermometer 121 for measuring environmental temperature, and the determination unit 122. The determination unit 122 determines whether or not the BPF correction coefficient converges within the optimal correction coefficient range, when the arithmetic process is performed to calculate the BPF correction coefficient. The determination unit 122 determines whether or not the temperature variation value, which is the difference between the environmental temperature when the BPF correction coefficient converges within the optimal correction coefficient range and the environmental temperature that is measured at the present time, is equal to or less than the set value. When the temperature variation value is equal to or less than the set value, the arithmetic unit 15 stops calculating the BPF correction coefficient. While the calculation of the BPF correction coefficient has been stopped, when the temperature variation value exceeds the set value, the arithmetic unit 15 restarts calculating the BPF correction coefficient. Accordingly, when the BPF correction coefficient converges within the optimal correction coefficient range, ACAL is stopped if the temperature variation value is equal to or less than the set value, thus allowing performing ACAL in an intermittent manner. Therefore, intermittently performing ACAL allows a reduction in power consumed by ACAL, as compared with the case of not performing ACAL in an intermittent manner.

### [c] Other Embodiments

The components described in the first and second embodiments are not necessarily physically configured as depicted in the drawings. In other words, the concrete distributed and integrated manner of the components is not limited to the drawings, but all or part of the components may be functionally and physically distributed or integrated in arbitrary units in accordance with various loads, usage state, and the like.

Furthermore, a central processing unit (CPU) (or a microcomputer such as an MPU (micro processing unit) and an MCU (micro controller unit)) may perform all or any part of the various processes performed in each device. All or any part of the various processes may be performed by a program that runs on the CPU (or microcomputer such as MPU and MCU) or by wired logic hardware.

For example, the base station device according to the first and second embodiments may be realized by the following hardware configuration.

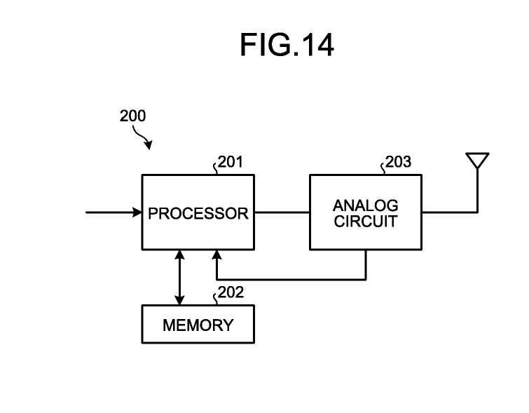

FIG. 14 is a drawing that depicts an example of the hardware configuration of a base station device. As depicted in FIG. 14, a base station device 200 has a processor 201, a memory 202, and an analog circuit 203. Examples of the processor 201 may include a CPU, a DSP (digital signal processor), and an FPGA (field programmable gate array). Examples of the memory 202 may include a RAM (random access memory), such as an SDRAM (synchronous dynamic random access memory), a ROM (read only memory), and a flash memory.

The various processes performed by the base station device 100 according to the first and second embodiments may be realized by running programs stored in the various memories such as a nonvolatile memory medium on the processor. In other words, programs corresponding to various processes performed by the digital processing unit 101 may be stored in the memory 202, and the programs may be executed on the processor 201. The analog circuit 104 is realized by the analog circuit 203.

Note that, the various processes performed by the base station device 100 according to the first and second embodiments are executed on the processor 201 in this embodiment, but not limited thereto, may be performed on a plurality of processors.

According to an aspect of the embodiment, it becomes possible to prevent an increase in power consumed by the arithmetic process and an increase in circuit size.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An arithmetic method comprising:
calculating a first correction coefficient for correcting distortion due to a power amplifier, based on a first feedback signal that has been fed back from an output of the power amplifier and an input signal before being input to the power amplifier; and
calculating a second correction coefficient for correcting a phase and an amplitude of a signal to be output from a filter disposed behind the power amplifier, based on a second feedback signal that has been fed back from an output of the filter and the input signal.

2. The arithmetic method according to claim 1, further comprising:
switching between a first feedback path for feeding back the output of the power amplifier and a second feedback path for feeding back the output of the filter in a time division manner;
when a feedback path is switched to the first feedback path, the first correction coefficient is calculated; and
when the feedback path is switched to the second feedback path, the second correction coefficient is calculated.

3. The arithmetic method according to claim 2, further comprising
when switching between the first feedback path and the second feedback path in a time division manner, delaying the second feedback signal that has been fed back from the output of the filter through the second feedback path by a predetermined time, based on a process time for calculating the first correction coefficient and a process time for a signal output from the power amplifier to pass through the filter.

4. The arithmetic method according to claim 1, further comprising:
measuring an environmental temperature;
determining whether or not the second correction coefficient converges within an optimal correction coefficient range, when the second correction coefficient is calculated;
determining whether or not a temperature variation value that is a difference between an environmental temperature when the second correction coefficient converges within the optimal correction coefficient range and an environmental temperature measured at the present time is equal to or less than a set value;
stopping calculating the second correction coefficient, when the temperature variation value is equal to or less than the set value; and
restarting calculating the second correction coefficient, when the temperature variation value exceeds the set value while the calculation of the second correction coefficient has been stopped.

5. A base station device comprising:
a power amplifier;
a filter disposed behind the power amplifier; and
an arithmetic unit that calculates a first correction coefficient for correcting distortion due to the power amplifier, based on a first feedback signal that has been fed back from an output of the power amplifier and an input signal before being input to the power amplifier, and that calculates a second correction coefficient for correcting a phase and an amplitude of a signal to be output from the filter, based on a second feedback signal that has been fed back from an output of the filter and the input signal.

6. An arithmetic circuit comprising:
an extraction processing unit that extracts a first error that is an error between a first feedback signal that has been fed back from an output of a power amplifier and an input signal before being input to the power amplifier, and that extracts a second error that is an error between a second feedback signal that has been fed back from an output of a filter disposed behind the power amplifier and the input signal; and
an arithmetic processing unit that calculates a first correction coefficient for correcting distortion due to the power amplifier based on the first error, and that calculates a second correction coefficient for correcting a phase and an amplitude of a signal to be output from the filter based on the second error.
